(19) United States
(12) Patent Application Publication
(10) Pub. No.: US 2002/0116678 A1
(43) Pub. Date: Aug. 22, 2002

(54) Error processing method and error processing apparatus of voice code data in QPSK system

(75) Inventor: Takeshi Hattori, Tokyo (JP)

Correspondence Address: YOUNG & THOMPSON, 745 SOUTH 23RD STREET 2ND FLOOR, ARLINGTON, VA, 22202

(73) Assignee: NEC CORPORATION, TOKYO (JP)

(21) Appl. No.: 10/067,867

(22) Filed: Feb. 8, 2002

(30) Foreign Application Priority Data
Feb. 9, 2001 (JP) 2001-033858

(51) Int. Cl. H03M 13/00

(52) U.S. Cl. 714/781

(57) ABSTRACT

In a digital communication system for modulating a voice code data by means of a QPSK system, and conducting radio communication, when a data error is detected in a base band processing section 2, an error symbol detecting section 5 identifies an error symbol having minimum unit length, and a conversion data determination processing section 6 selects a symbol data having the second-closest phase from the phase content of the symbol, and conducts data conversion in a voice code data conversion section 7. Thereby, it becomes a data approximate to a normal data with a high possibility, and the deterioration of voice quality when an error occurs is suppressed to a minimum.

### BACKGROUND OF THE INVENTION

The present invention relates to an error processing method and an error processing apparatus of a voice code data in digital communication, and especially, to an error processing system and an error processing apparatus for reducing the deterioration of voice quality on a side of a receiver in case that an error of a voice code data using a QPSK (Quadrature Phase Shift Keying) system occurs.

A conventional digital communication, for example a digital communication system such as a simplified type portable telephone system (abbreviated to PHS, hereinafter) is a system for conducting modulation and demodulation of an ADPCM voice data by means of a π/4QPSK system. The PHS does not have an error correction code, and has a transmission frame constructed of a unique word for detecting synchronism establishment and a CRC for detecting a frame error, and in case of detecting pulling out of synchronism due to discrepancy of the unique word on a side of a receiver or in case of detecting a frame error from CRC information, the PHS uses mute processing for making a whole of an error frame a mute data before demodulation as error processing or repetitive frame processing in which a previous frame is repeatedly used.

However, in the above-described mute processing, since the voice data suddenly becomes mute, there is a defect that a click noise occurs. Also, on the processing in which a previous frame is repeatedly used, especially in ADPCM voice in which a difference value to a previous data is coded, a voice code data after an error is eliminated is not normal. Accordingly, in the above-described error processing method, the prevention of a noise is insufficient.

Since, in the above-mentioned error processing method, an effect of the noise prevention is insufficient, an error processing method of reducing a difference in case that the difference between ADPCM (adaptive difference PCM) voice code data is a maximum has been proposed. Further, although an error processing method of suppressing the deterioration of voice quality by determining an error occurrence part out of a frame where an error is detected and applying data conversion to said part has been proposed, it is difficult to say that it is perfect.

In order to overcome such a defect in the prior art, the inventors previously proposed “ERROR PROCESSING APPARATUS AND ERROR PROCESSING METHOD OF VOICE CODE DATA” (U.S. Pat. No. 2,927,242: JP-A-22938/1998). Here, a voice code data error processing method is characterized in that, when a transmission frame including a voice code data is received, it is detected from CRC information included in this transmission frame whether or not there is an error of the transmission frame, and phase content of the received voice code data is detected for every symbol having predetermined bit length and is stored, and when a frame error is detected, the stored phase content is compared with a reference set value indicating a phase difference allowable range set in advance and it is determined whether or not the phase content is within the allowable range, and when it is determined to be outside the allowable range, only the voice code data including the corresponding symbol is converted so that a difference to a normal voice code data just before it becomes small, and an error processing apparatus comprising each element having a function appropriate for executing the above-mentioned each function, respectively, is disclosed.

In addition, an arrangement of the transmission frame in such a communication system will be disclosed referring to FIG. 3. As shown in FIG. 3, this transmission frame is constructed of transient response lump time (R) 10, a start symbol (SS) 11, a preamble (PR) 12, a unique word (UW) 13, a channel identifying code (CI) 14, an SACCH (SA) 15, an ADPCM voice code data frame 16, and a CRC 17. And, the transmission frame is arranged so that a frame error is detected from CRC information within the CRC 17.

The problem in the prior art is that, although error processing for converting a corresponding data is conducted when an error of the voice code data is detected, noise prevention and voice quality are not sufficient. The reason thereof is that, since the conversion data is a mute data or a repetitive data, a difference to a normal data is large, which is not appropriate.

### SUMMARY OF THE INVENTION

A task of the present invention is to solve the above-mentioned problem that the conventional error processing system has, and to provide error processing method and processing apparatus of a voice code data in a QPSK system, capable of improving the deterioration of voice quality when an error occurs by using a data that is determined so as to be close to a normal data as a conversion data of an error voice code data.

An error processing method of a voice code data in accordance with the present invention is characterized in that, in a digital communication system for modulating a coded voice code data by means of a QPSK system, and conducting radio communication, an error voice code data is detected on a side of a receiver by means of error detecting means, and error processing is executed by determining a conversion data appropriate for said detected error voice code data and converting it. Accordingly, compared with an error processing method in which a conventional conversion data is used, voice quality is improved.

As shown in FIG. 1, in a digital communication system for modulating a voice code data by means of a QPSK system, and conducting radio communication, an error processing apparatus of a voice code data in accordance with the present invention has means 2 for detecting a data error from CRC information when receiving a transmission frame constructed of a voice code data and a CRC, means 5 for identifying an error data having minimum unit length when, the data error is detected by the detecting means, and conversion processing means 7 for determining an appropriate conversion data and conducting data conversion.

Also, the above-described conversion means has means 4 for storing phase content of a voice code data using the QPSK system for every symbol having minimum unit length, determination processing means 6 for comparing phases with each other of two symbols adjacent to an error symbol on an I-Q chart, based on phase content (FIG. 2) of a corresponding symbol when an error is detected by the detecting means, and determining a symbol having a close phase, and conversion processing means 7 for conducting conversion of a data transmitted by said determination processing means.

According to the error processing method of a voice code data in the QPSK system in accordance with the present invention, the phase content of the voice code data in accordance with the QPSK system is detected for every symbol having the minimum unit length, and the error symbol is identified when the data error occurs, and the phase content of the symbol is compared with the phases of the two symbols adjacent thereto on the I-Q chart, and the conversion to a symbol data having closer phase content is conducted. As a result, a data approximate to a normal data can be restored with a high probability, and the deterioration of voice quality can be suppressed to a minimum. In addition, any error symbol identifying method can be used.

According to the error processing apparatus of a voice code data in the QPSK system in accordance with the present invention, processing appropriate for executing the above-mentioned processing method is executed in each element constituting the apparatus, and appropriate voice data decoding processing is conducted.

### BRIEF DESCRIPTION OF THE DRAWING

This and other objects, features and advantages of the present invention will become more apparent upon a reading of the following detailed description and drawings, in which:

FIG. 1 is a block diagram showing an arrangement of a voice control section of a digital communication system using a QPSK system appropriate for the present invention;

FIG. 2 is a view showing the coding of a π/4 shift QPSK system and

FIG. 3 is a view showing a format example of a transmission frame used for the digital communication system using the QPSK system on which the present invention focuses.

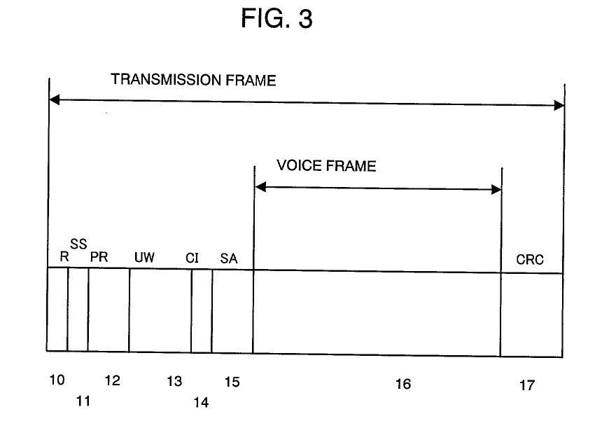

### DESCRIPTION OF THE EMBODIMENTS

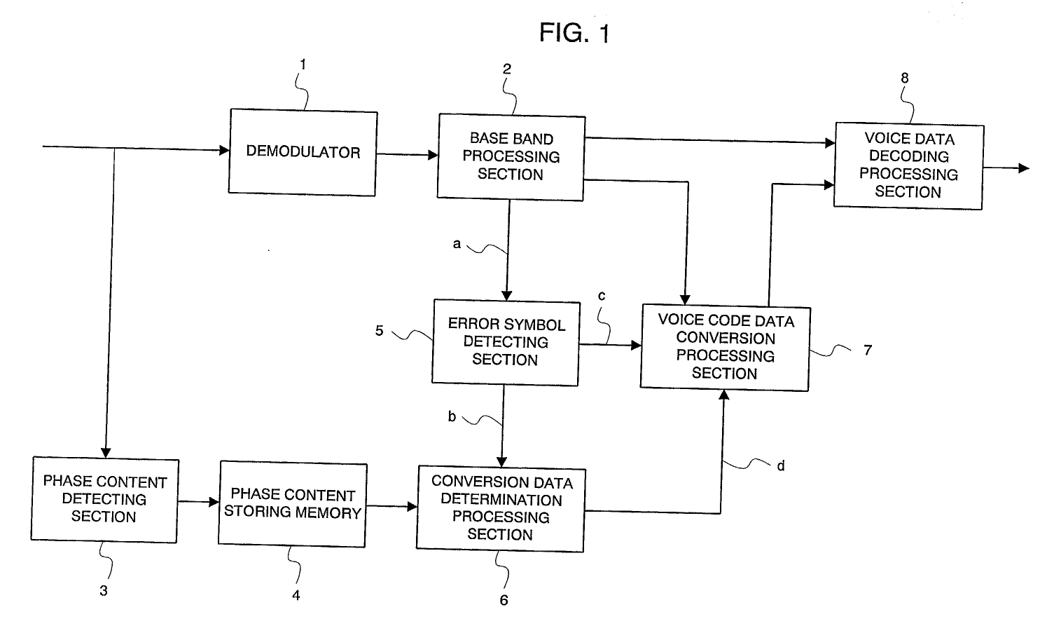

Next, an embodiment of the present invention will be explained in detail referring to drawings. FIG. 1 shows a main arrangement of a digital communication system using a QPSK system, to which the present invention is applied, and shows an arrangement of a voice control section of a receiver. The voice control section of the present invention, which conducts error processing of a voice code data, is constructed of a demodulator 1 for demodulating a received voice code data, a base band processing section 2 for detecting a data error from CRC information in a transmission frame after demodulation, a phase content detecting section 3 for detecting phase content of a voice code data of the QPSK system for every symbol, a phase content storing memory 4 for storing the detected phase content, an error symbol detecting section 5 for identifying an error symbol, a conversion data determination processing section 6 for determining 1 symbol data to be concerted from phase content of the error symbol when a data error is detected, a voice data decoding processing section 8 for decoding the voice code data, and a voice code data conversion processing section 7 for converting only the error symbol, and sending it to said voice data decoding processing section 8.

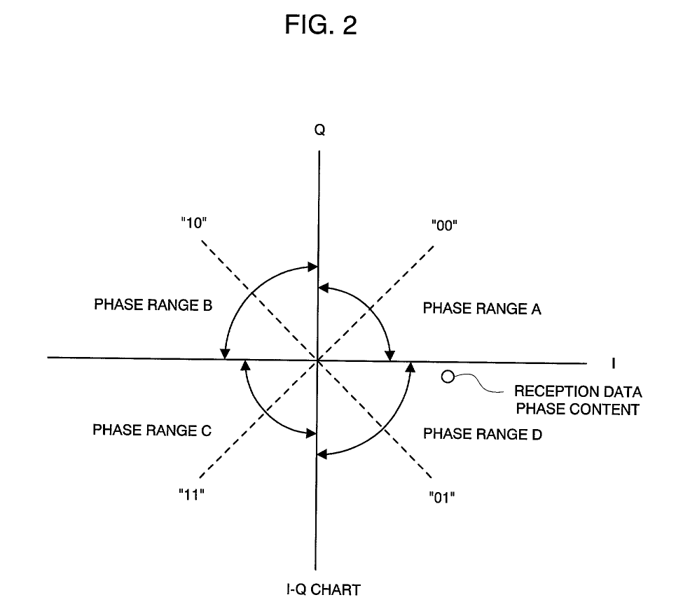

FIG. 2 is a view showing condition of the coding of a π/4 shift QPSK system. The π/4 shift QPSK system is a system in which a symbol data of “00” is allocated if phase content from a reference phase is +45 degrees (a phase range A) on an I-Q chart, a symbol data of “10” is allocated if the phase content is +135 degrees (a phase range B), a symbol data of “11” is allocated if the phase content is −135 degrees (a phase range C), and a symbol data of “01” is allocated if the phase content is −45 degrees (a phase range D).

If reception data phase content shown by a white circle on a side below an I axis in the drawing is phase content of the error symbol, “00” in the phase range A adjacent thereto and “11” in the phase range C are compared with each other, and “00” that has closer phase content is determined as one suitable for a conversion data.

An operation of the voice control section of the receiver in the digital communication system using the QPSK system, to which the present invention is applied, will be explained referring to the drawings. This system modulates the voice code data by means of the QPSK system and conducts radio communication, and the transmission frame is constructed of a voice code data and a CRC.

The received transmission frame is demodulated in the demodulator 1 shown in FIG. 1, and is output to the base band processing section 2. Also, phase content of the QPSK system of the voice code data in the received transmission frame is detected for every symbol in the phase content detecting section 3, and is written in the phase content storing memory 4.

The base band processing section 2 to which the demodulated transmission frame is input determines a frame error when detecting an error more than or equal to 1 bit from CRC information in the transmission frame. And, in accordance with the existence of the frame error, the base band processing section 2 sends the voice code data to the voice data decoding processing section 8 if the frame error does not exist. If the frame error exists, the base band processing section transmits frame error information a to the error symbol detecting section 5, and sends the voice code data to the voice code data conversion processing section 7.

When receiving the frame error information a from the base band processing section 2, the error symbol detecting section 5 identifies an error symbol, and transmits error symbol position information b and c to the conversion data determination processing section 6 and the voice code data conversion processing section 7. The conversion data determination processing section 6 reads from the phase content storing memory 4 phase content for every symbol of the transmission frame in which the frame error occurs, and determines a conversion data by means of comparison thereof with the error symbol position information b and sends conversion data information d to the voice code data conversion processing section 7.

In the determination of the conversion data, phase content of an error symbol and phase content of a symbol adjacent thereto are compared with each other on the I-Q chart shown in FIG. 2, a symbol data having a closer phase is determined as the conversion data. In case that a frame error occurs, the voice code data conversion processing section 7 receives the voice code data a of the error frame from the base band processing section 2. The voice code data conversion processing section 7 receives the error symbol position information c from the error symbol detecting section 5 and the conversion data information d from the conversion data determination processing section 6, respectively, and rewrites the corresponding error symbol to a conversion data and transmits the voice code data to the voice decoding processing section 8.

The ADPCM decoding processing section 8 receives the voice code data from the base band processing section 2 or the voice code data converted from the ADPCM voice code data conversion processing section 7, and demodulates an analog voice data. In such a manner, by detecting the phase content of the received data for every symbol, and converting it into a symbol data having the second-closest phase from the phase content of the error symbol when the data error is detected, the deterioration of voice quality can be reduced.

According to the error processing method of the voice code data in the QPSK system in accordance with the present invention, since the phase content of the voice data of the QPSK system is detected for every symbol, and a symbol data having the second-closest phase from the phase content of the identified error symbol is selected and the data conversion thereof is conducted, a data approximate to a normal data is obtained with a high possibility. Accordingly, the deterioration of voice quality when a frame error occurs can be suppressed to a minimum.

According to the error processing apparatus of the voice code data in the QPSK system in accordance with the present invention, while it has a comparatively simple arrangement, the above-mentioned error processing method is executed, and the expected objective can be accomplished.

What is claimed is:

1. An error processing method of a voice code data, characterized in that, in a digital communication system for modulating a coded voice code data by means of a QPSK system, and conducting radio communication, an error voice code data is detected on a side of a receiver by means of error detecting means, and error processing is executed by determining a conversion data appropriate for said detected error voice code data and converting it.

2. An error processing method of a voice code data in a digital communication system for modulating a coded voice code data by means of a QPSK system and conducting radio communication, comprising the steps of
detecting an error voice code data on a side of a receiver by error detector,
executing error process by determining a conversion data appropriate for said detected error voice code data and converting it.

3. An error processing method of a voice code data recited in claim 2, wherein said step of executing error process further comprising:
detecting phase content of a voice code data of the QPSK system for every predetermined bit length and storing it,
reading phase content of an error symbol in case that the error voice code data is detected and determining a symbol data in the second-closest phase range
converting an error symbol part into the determined symbol data, and improving voice quality.

4. An error processing method of a voice code data recited in claim 3, wherein said predetermined bit length is 1 symbol (2 bits).

5. An error processing apparatus of a voice code data in a digital communication system for modulating a coded voice code data by means of a QPSK system and conducting radio communication, comprising:
means for detecting an error voice code data on a side of a receiver, and
means for determining a conversion data appropriate for the error voice code data and converting it.

6. An error processing apparatus of a voice code data recited in claim 5, characterized in that, the means for determining an appropriate conversion data to the error voice code data and converting it has means for detecting phase content of a voice code data of the QPSK system for every predetermined bit length, and storing it, means for reading phase content of an error symbol in case that the error voice code data is detected, and determining a symbol data in the second-closest phase range, and means for converting an error symbol part into the determined symbol data, and improving voice quality.

7. An error processing apparatus of a voice code data recited in claim 6, wherein said predetermined bit length is 1 symbol (2 bits).

8. An error processing apparatus of a voice code data, characterized in that, the apparatus has:
a demodulator for demodulating a received voice code data,
a base band processing section for detecting a data error from CRC information in a transmission frame after demodulation,
a phase content detecting section for detecting phase content of a voice code data of a QPSK system for every symbol,
a phase content storing memory for storing the detected phase content,
an error symbol detecting section for identifying an error symbol,
a conversion data determination processing section for determining 1 symbol data to be concerted from phase content of the error symbol when a data error is detected,
a voice data decoding processing section for decoding the voice code data, and
a voice code data conversion processing section for converting only the error symbol, and sending it to said voice data decoding processing section.
